(19) United States
(12) Patent Application Publication
(10) Pub. No.: US 2023/0187368 A1
(43) Pub. Date: Jun. 15, 2023

(54) HYBRID SEMICONDUCTOR PACKAGE FOR IMPROVED POWER INTEGRITY

(71) Applicant: Intel Corporation, Santa Clara, CA (US)

(72) Inventors: Seok Ling LIM, Kulim Kedah (MY); Bok Eng CHEAH, Gelugor Pulau Penang (MY); Jenny Shio Yin ONG, Bayan Lepas Pulau Pinang (MY); Jackson Chung Peng KONG, Tanjung Tokong Pulau Penang (MY); Kooi Chi OOI, Gelugor Pulau Pinang (MY)

(21) Appl. No.: 17/548,628

(22) Filed: Dec. 13, 2021

(51) Int. Cl. H01L 23/538; H01L 23/13; H01L 21/48

(52) U.S. Cl. CPC H01L 23/5386; H01L 23/13; H01L 23/5383; H01L 23/5385; H01L 21/4857

(57) ABSTRACT

The present disclosure generally relates to an electronic assembly. The electronic assembly may include a first substrate including a first surface, an opposing second surface and a recess opening extending through the first surface. The electronic assembly may also include a power delivery mold frame including a first mold surface, an opposing second mold surface, a plurality of first metal planes and a plurality of second metal planes extending between the first and second mold surfaces, the power delivery mold frame arranged in the recess opening and coupled to the first substrate through the first mold surface. The electronic assembly may further include a second substrate including a subsequent first surface, an opposing subsequent second surface, the second substrate coupled to the power delivery mold frame through a plurality of first solder bumps and further coupled to the first substrate through a plurality of second solder bumps at the subsequent first surface.

### BACKGROUND

There are challenges in addressing escalating power integrity requirements for high performance computing devices, e.g., a silicon chiplet or disaggregation architecture on a 2.5D stacked package. The respective compute and graphics silicon tiles or chiplets may require robust power delivery network (PDN) for improved processing capabilities.

Current solutions to address the above-mentioned challenges include:
Increased package substrate layer count, e.g., one or more power (Vcc) and ground (Vss) reference planes to meet the power integrity and/or power supply noise induced jitter (PSIJ) performance target.
Reduction of silicon ICC_{Max} threshold or increased total count of through silicon vias (TSV) interconnects to mitigate device reliability risks.

The disadvantages of the above-mentioned solutions may include, but not limited to, increased silicon and/or package substrate footprint expansion due to additional interconnects and/or layer count that inhibits device form-factor miniaturization; and device performance impact or defeature, e.g., reduced maximum frequency (Fmax) threshold for the compute and/or graphic cores.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the present disclosure. The dimensions of the various features or elements may be arbitrarily expanded or reduced for clarity. In the following description, various aspects of the present disclosure are described with reference to the following drawings, in which:

FIG. 1A shows a cross-sectional view of an electronic assembly according to an aspect of the present disclosure;

FIG. 1B shows a top view layout of the electronic assembly according to the aspect as shown in FIG. 1A;

FIG. 2 shows a cross-sectional view of an electronic assembly according to another aspect of the present disclosure;

FIG. 3 shows a cross-sectional view of an electronic assembly according to yet another aspect of the present disclosure;

FIGS. 4A through 4F show cross-sectional views directed to an exemplary simplified process flow for forming an electronic assembly according to an aspect that is generally similar to that shown in FIG. 1A of the present disclosure;

FIG. 5 shows an illustration of a computing device that includes an electronic assembly according to a further aspect of the present disclosure; and

FIG. 6 shows a flow chart illustrating a method for forming an electronic assembly according to an aspect of the present disclosure.

### DETAILED DESCRIPTION

The following detailed description refers to the accompanying drawings that show, by way of illustration, specific details and aspects in which the present disclosure may be practiced. These aspects are described in sufficient detail to enable those skilled in the art to practice the present disclosure. Various aspects are provided for devices, and various aspects are provided for methods. It will be understood that the basic properties of the devices also hold for the methods and vice versa. Other aspects may be utilized and structural, and logical changes may be made without departing from the scope of the present disclosure. The various aspects are not necessarily mutually exclusive, as some aspects may be combined with one or more other aspects to form new aspects.

Present disclosure attempt to address the trade-off of additional package substrate layer count required, e.g., additional power (Vcc) and/or ground (Vss) reference planes to achieve stringent DC resistance and AC loop inductance for improved device performance. Present disclosure may also mitigate device reliability risks ascribed to constrained current carrying capability with reduced interconnect geometry, e.g., miniaturized through silicon vias (TSVs).

Technical advantages of the present disclosure may include, but not limited to:
Improved electrical (power integrity) performance through streamlined and localized power delivery network (PDN) especially for 2.5D/3D stacked die packages; improved AC loop inductance can be achieved through the tightly coupled Vcc-Vss network. Reduced DC resistance can be also achieved through increased power plane thickness (e.g., >30 μm) and/or geometry (e.g., metal volume) without being restricted by conventional package manufacturing assembly process, i.e., homogenous metal layer thickness (approximately 15 μm) across signal routing and the power delivery network.
Improved device reliability, i.e., increased Imax capacity through reduced DC resistance can be achieved through enhanced interconnect volume; increased Imax threshold allows higher rating-power and performance for the compute and graphic tiles.
Platform miniaturization via low-profile package substrate thickness through metal layer count especially power plane reduction; package footprint or real-estate can be minimized through scalable power and ground plane metal density in z-axis with the power delivery mold frame module.

The present disclosure generally relates to a device, e.g., an electronic assembly. The electronic assembly may include a first substrate including a first surface, an opposing second surface and a recess opening extending through the first surface. The electronic assembly may also include a power delivery mold frame including a first mold surface, an opposing second mold surface, a plurality of first metal planes and a plurality of second metal planes extending between the first and second mold surfaces, the power delivery mold frame arranged in the recess opening and coupled to the first substrate through the first mold surface. The electronic assembly may further include a second substrate including a subsequent first surface, an opposing subsequent second surface, the second substrate coupled to the power delivery mold frame through a plurality of first solder bumps and further coupled to the first substrate through a plurality of second solder bumps at the subsequent first surface.

In various aspects, the respective first substrate and the second substrate may include a silicon substrate, a glass substrate, an organic substrate, or a ceramic substrate.

In various aspects, the power delivery mold frame may further include one or more mold layers, wherein the plurality of first and second metal planes may be spaced apart by the one or more mold layers.

In various aspects, the plurality of first metal planes may be arranged adjacent the plurality of second metal planes.

In various aspects, the plurality of first metal planes may include a first thickness or volume, the plurality of second metal planes may include a second thickness or volume equal or greater than the first thickness or volume.

In various aspects, the plurality of first metal planes may be associated to a ground reference voltage (Vss), and the plurality of second metal planes may be associated to a power supply reference voltage (Vcc).

In various aspects, the second mold surface may extend beyond the first surface.

In various aspects, the plurality of first solder bumps may include a first diameter and the plurality of second solder bumps may include a second diameter greater than the first diameter.

In various aspects, the electronic assembly may further include one or more metal redistribution layers (RDLs) arranged on the respective second and/or subsequent second surfaces.

In various aspects, the electronic assembly may further include one or more electronic components arranged on the respective second and/or subsequent second surfaces and coupled to the power delivery mold frame through a plurality of substrate contact pads and vias.

In various aspects, the one or more electronic components may include a central processing unit (CPU), a graphic processing unit (GPU), a memory device, a neural network processor, an input-output (I/O) tile, a voltage regulator, an inductor, or a capacitor.

The present disclosure also generally relates to a computing device. The computing device may include a circuit board and an electronic assembly coupled to the circuit board. The electronic assembly may include a first substrate including a first surface, an opposing second surface and a recess opening extending through the first surface. The electronic assembly may also include a power delivery mold frame including a first mold surface, an opposing second mold surface, a plurality of first metal planes and a plurality of second metal planes extending between the first and second mold surfaces, the power delivery mold frame arranged in the recess opening and coupled to the first substrate through the first mold surface. The electronic assembly may further include a second substrate including a subsequent first surface, an opposing subsequent second surface, the second substrate coupled to the power delivery mold frame through a plurality of first solder bumps and further coupled to the first substrate through a plurality of second solder bumps at the subsequent first surface.

The present disclosure further generally relates to a method. The method may include forming a first substrate including a first surface, an opposing second surface and a recess opening extending through the first surface. The method may also include forming a power delivery mold frame including a first mold surface, an opposing second mold surface, a plurality of first metal planes and a plurality of second metal planes extending between the first and second mold surfaces. The method may include arranging the power delivery mold frame in the recess opening and coupling the power delivery mold frame to the first substrate through the first mold surface. The method may further include forming a second substrate including a subsequent first surface, an opposing subsequent second surface, coupling the second substrate to the power delivery mold frame through a plurality of first solder bumps and further coupling the second substrate to the first substrate through a plurality of second solder bumps at the subsequent first surface.

To more readily understand and put into practical effect the present disclosure, particular aspects will now be described by way of examples and not limitations, and with reference to the drawings. For the sake of brevity, duplicate descriptions of features and properties may be omitted.

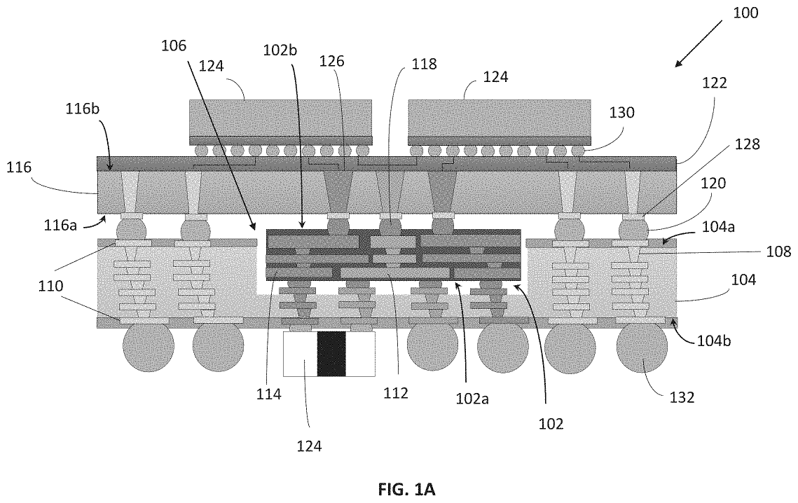

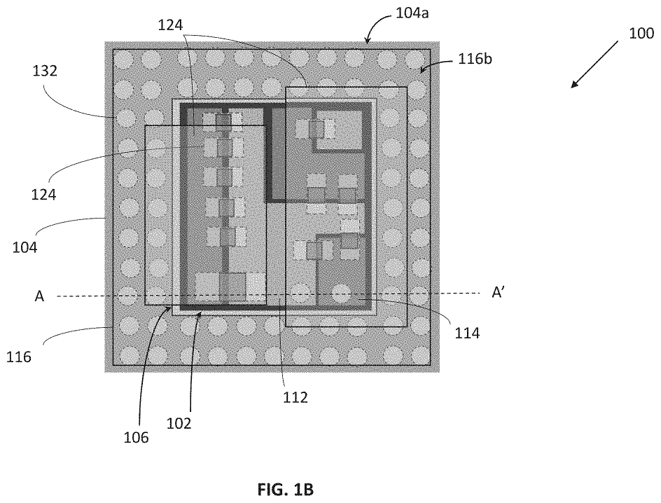

FIG. 1A shows a cross-sectional view of an electronic assembly according to an aspect of the present disclosure. In this illustration, it is showed an electronic assembly 100 (or a semiconductor package), e.g., a 2.5D/3D stacked die package or a multichip package (MCP) with a hybrid power delivery mold frame 102 for improved electrical performance and device miniaturization. The cross-section is taken along the A-A′ line of FIG. 1B.

The term “multichip package” generally refers to an electronic assembly that may include two or more dies, chips, or chiplets (interchangeably used herein) that may be arranged laterally along the same plane. As different types of devices cater to different types of applications, more dies may be required in some systems to meet the requirements of high performance applications. Accordingly, to obtain better performance and higher density, in various aspects of the present disclosure, the electronic assembly may include multiple dies arranged laterally along the same plane, and additional die(s) arranged in a different plane, i.e., 2.5/3D packaging.

In various aspects, the electronic assembly 100 may include a first substrate 104. In various aspects, the first substrate 104 may be, e.g., an organic substrate or a ceramic substrate. The first substrate 104 may include a first surface 104a, an opposing second surface 104b and a recess opening 106 extending through the first surface 104a. In the aspect shown in FIG. 1A, the recess opening may extend from the first surface 104a towards, but not contacting, the second surface 104b.

The first substrate 104 may have contact pads, electrical interconnects and routings, and other features, which may or may not be shown in any of the present figures and which are conventional features known to a person skilled in the art. In the aspect shown in FIG. 1A, the first substrate 104 may include a plurality of micro-vias 108 embedded therein. The first substrate 104 may further include a plurality of first contact pads 110 at the first surface 104a and the second surface 104b. The first substrate 104 may include a plurality of solder balls 132 for coupling to, e.g., a motherboard (not shown).

In various aspects, the power delivery mold frame 102 may include a first mold surface 102a and an opposing second mold surface 102b, and may be arranged in the recess opening 106. The power delivery mold frame 102 may be coupled to the first substrate 104 through the first mold surface 102a. In one aspect, the power delivery mold frame 102 may include a plurality of first metal planes 112 and a plurality of second metal planes 114. In various aspects, the plurality of second metal planes 114 may be arranged adjacent the plurality of first metal planes 112. The plurality of first metal planes 112 and the plurality of second metal planes 114 may extend between the first and second mold surfaces 102a, 102b to facilitate a reduced AC loop inductance.

In various aspects, the power delivery mold frame 102 may include one or more mold layers. For example, the one or more mold layers may be an epoxy polymer resin layer or a silicone layer.

In various aspects, the plurality of first and second metal planes 112, 114 may be spaced apart by the one or more mold layers. In one aspect, the plurality of first metal planes 112 may be associated to a ground reference voltage (Vss). In one aspect, the plurality of second metal planes 114 may be associated to a power supply reference voltage (Vcc).

In various aspects, the plurality of first metal planes 112 may include a first thickness or volume and the plurality of second metal planes 114 may include a second thickness or volume. Advantageously, the second thickness or volume may be configured to be equal or greater than the first thickness or volume for a reduced DC resistance and an improved current carrying capacity.

In an aspect, the first substrate 104 may include a plurality of metal traces having a third thickness lesser than the second thickness extending between the first and second surfaces 104a, 104b for signal transmissions. In an aspect, the third thickness may range from 10 μm to 20 μm.

In the aspect shown in FIG. 1A, the second mold surface 102b may extend beyond the first surface 104a. In other aspects, the second mold surface 102b may not extend beyond the first surface 104a.

In various aspects, the power delivery mold frame 102 may include a thickness ranging from 100 μm to 900 μm. In other aspects, the power delivery mold frame 102 may include a dimension ranging from 2 mm×2 mm to 8 mm×8 mm.

In various aspects, the electronic assembly 100 may include a second substrate 116, such as a silicon or glass interposer substrate. The second substrate 116 may include a subsequent first surface 116a and an opposing subsequent second surface 116b.

The second substrate 116 may include a plurality of through silicon vias (TSVs) 126 embedded therein. The second substrate 116 may further include a plurality of second contact pads 128 at the subsequent first surface 116a.

The second substrate 116 may be arranged on the first surface 104a. In various aspects, the second substrate 116 may be coupled to the power delivery mold frame 102 through a plurality of first solder bumps 118 at the second mold surface 102b. The second substrate 116 may be further coupled to the first substrate 104 through a plurality of second solder bumps 120 at the subsequent first surface 116a.

In the aspect shown in FIG. 1A and as mentioned in an earlier paragraph, the second mold surface 102b may extend beyond the first surface 104a. As such, the plurality of first solder bumps 118 may include a first diameter and the plurality of second solder bumps 120 may include a second diameter greater than the first diameter. In an aspect, the second diameter may range from 40 μm to 80 μm.

In various aspects, the first and/or second substrates 104, 116 may include one or more metal redistribution layers (RDLs) 122. The one or more metal redistribution layers (RDLs) 122 may be arranged on the respective second and/or subsequent second surfaces 104b, 116b.

In various aspects, one or more electronic components 124 may be arranged on the respective second and/or subsequent second surfaces 104b, 116b. In the aspect shown in FIG. 1A, one electronic component 124 may be coupled to the power delivery mold frame 102 through the plurality of first contact pads 110 and micro-vias 108 at the second surface 104b. Two additional electronic components 124 may be coupled to the power delivery mold frame 102 through the plurality of second contact pads 128 and through silicon vias 126 at the subsequent second surface 116b. The one or more electronic components 124 may be coupled to the first and/or second substrates 104, 116 through micro-bumps 130.

In various aspects, the one or more electronic components 124 may include a computing and/or transceiver device, e.g., a central processing unit (CPU), a graphic processing unit (GPU), a memory device, a neural network accelerator, a field programmable gate array (FPGA), a platform controller hub (PCH) chipset, or an input-output (I/O) tile. In other aspects, the one or more electronic components 124 may include a passive component, e.g., a voltage regulator, an inductor, or a capacitor.

FIG. 1B shows a top view layout of the electronic assembly 100 according to the aspect as shown in FIG. 1A. The first substrate 104 may include a footprint or perimeter. The second substrate 116 may include a footprint. The power delivery mold frame 102 may include a footprint.

In the aspect shown in FIG. 1B, the footprint of the power delivery mold frame 102 may fall within the perimeter of the first and second substrates 104, 116. In one aspect, the power delivery mold frame 102 may be disposed in the recess opening 106 of the first substrate 104. The footprint of the second substrate 116 may fall within the perimeter of the first substrate 104. Alternatively, the second substrate 116 may have the same sized perimeter as the first substrate 104.

In this top view, the first surface 104a, the subsequent second surface 116b, and the plurality of solder balls 132 (dashed circles) may be seen.

In the aspect shown in FIG. 1B, the respective first metal plane 112 and second metal plane 114 may each include a footprint which may fall within the perimeter of the power delivery mold frame 102.

The plurality of electronic components 124 may also been seen from this top view. The plurality of electronic components 124 may be coupled to the second substrate 116 at the subsequent second surface 116b. In the aspect shown in FIG. 1B, a footprint of each electronic component 124 may overlap with footprints of the power delivery mold frame 102 and the first substrate 104.

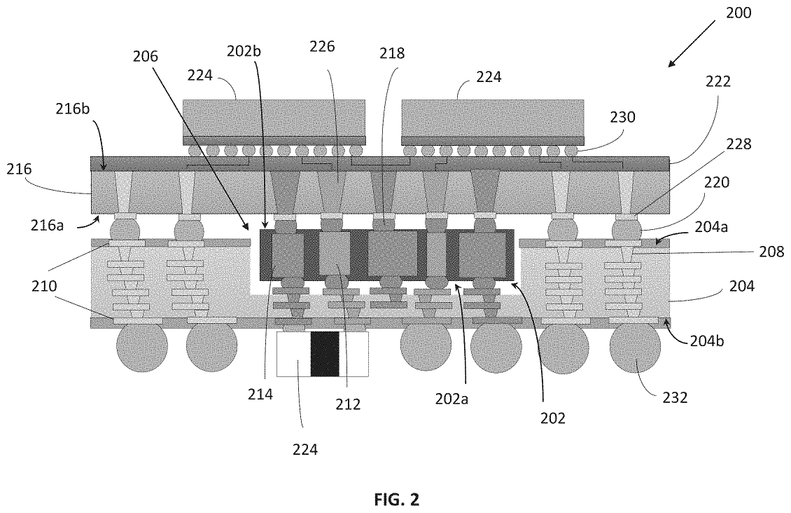

FIG. 2 shows a cross-sectional view of an electronic assembly according to another aspect of the present disclosure for improved device power integrity and miniaturization. The electronic assembly 200 may be similar to the electronic assembly 100 of FIG. 1A and may include additional variations and components as described below.

In various aspects, the electronic assembly 200 may include a first substrate 204. In various aspects, the first substrate 204 may be, e.g., an organic substrate or a ceramic substrate. The first substrate 204 may include a first surface 204a, an opposing second surface 204b and a recess opening 206 extending through the first surface 204a. In the aspect shown in FIG. 2, the recess opening may extend from the first surface 204a towards, but not contacting, the second surface 204b.

The first substrate 204 may have contact pads, electrical interconnects and routings, and other features, which may or may not be shown in any of the present figures and which are conventional features known to a person skilled in the art. In the aspect shown in FIG. 2, the first substrate 204 may include a plurality of micro-vias 208 embedded therein. The first substrate 204 may further include a plurality of first contact pads 210 at the first surface 204a and the second surface 204b. The first substrate 204 may include a plurality of solder balls 232 for coupling to, e.g., a motherboard (not shown).

In various aspects, the power delivery mold frame 202 may include a first mold surface 202a and an opposing second mold surface 202b, and may be arranged in the recess opening 206. The power delivery mold frame 202 may be coupled to the first substrate 204 through the first mold surface 202a. In one aspect, the power delivery mold frame 202 may include a plurality of first metal planes 212 and a plurality of second metal planes 214. In various aspects, the plurality of second metal planes 214 may be arranged adjacent the plurality of first metal planes 212. In an aspect, the plurality of first and second metal planes 212, 214 may extend orthogonal to the first and second mold surfaces 202a, 202b to achieve a localized power delivery network with reduced footprint.

In one aspect, the plurality of first metal planes 212 may be associated to a ground reference voltage (Vss). In one aspect, the plurality of second metal planes 214 may be associated to a power supply reference voltage (Vcc), e.g., a 1.0V, a 1.5V, a 1.8V or a 3.3V supply voltage, respectively.

In various aspects, the plurality of first metal planes 212 may include a first thickness or volume and the plurality of second metal planes 214 may include a second thickness or volume. Advantageously, the second thickness or volume may be configured to be equal or greater than the first thickness or volume for a reduced DC resistance and an improved current carrying capacity.

In an aspect, the first substrate 204 may include a plurality of metal traces having a third thickness lesser than the second thickness extending between the first and second surfaces 204a, 204b for signal transmissions. In an aspect, the third thickness may range from 10 μm to 20 μm.

In the aspect shown in FIG. 2, the second mold surface 202b may extend beyond the first surface 204a. In other aspects, the second mold surface 202b may not extend beyond the first surface 204a.

In various aspects, the power delivery mold frame 202 may include a thickness ranging from 100 μm to 900 μm. In other aspects, the power delivery mold frame 202 may include a dimension ranging from 2 mm×2 mm to 8 mm×8 mm.

In various aspects, the electronic assembly 200 may include a second substrate 216, such as a silicon or glass interposer substrate. The second substrate 216 may include a subsequent first surface 216a and an opposing subsequent second surface 216b.

The second substrate 216 may include a plurality of through silicon vias (TSVs) 226 embedded therein. The second substrate 216 may further include a plurality of second contact pads 228 at the subsequent first surface 216a.

The second substrate 216 may be arranged on the first surface 204a. In various aspects, the second substrate 216 may be coupled to the power delivery mold frame 202 through a plurality of first solder bumps 218 at the second mold surface 202b. The second substrate 216 may be further coupled to the first substrate 204 through a plurality of second solder bumps 220 at the subsequent first surface 216a.

In the aspect shown in FIG. 2 and as mentioned in an earlier paragraph, the second mold surface 202b may extend beyond the first surface 204a. As such, the plurality of first solder bumps 218 may include a first diameter and the plurality of second solder bumps 220 may include a second diameter greater than the first diameter. In an aspect, the second diameter may range from 40 μm to 80 μm.

In various aspects, the first and/or second substrates 204, 216 may include one or more metal redistribution layers (RDLs) 222. The one or more metal redistribution layers (RDLs) 222 may be arranged on the respective second and/or subsequent second surfaces 204b, 216b.

In various aspects, one or more electronic components 224 may be arranged on the respective second and/or subsequent second surfaces 204b, 216b. In the aspect shown in FIG. 2, one electronic component 224 may be coupled to the power delivery mold frame 202 through the plurality of first contact pads 210 and micro-vias 208 at the second surface 204b. Two additional electronic components 224 may be coupled to the power delivery mold frame 202 through the plurality of second contact pads 228 and through silicon vias 226 at the subsequent second surface 216b. The one or more electronic components 224 may be coupled to the first and/or second substrates 204, 216 through micro-bumps 230.

In various aspects, the one or more electronic components 224 may include a computing and/or transceiver device, e.g., a central processing unit (CPU), a graphic processing unit (GPU), a memory device, a neural network accelerator, a field programmable gate array (FPGA), a platform controller hub (PCH) chipset, or an input-output (I/O) tile. In other aspects, the one or more electronic components 224 may include a passive component, e.g., a voltage regulator, an inductor, or a capacitor.

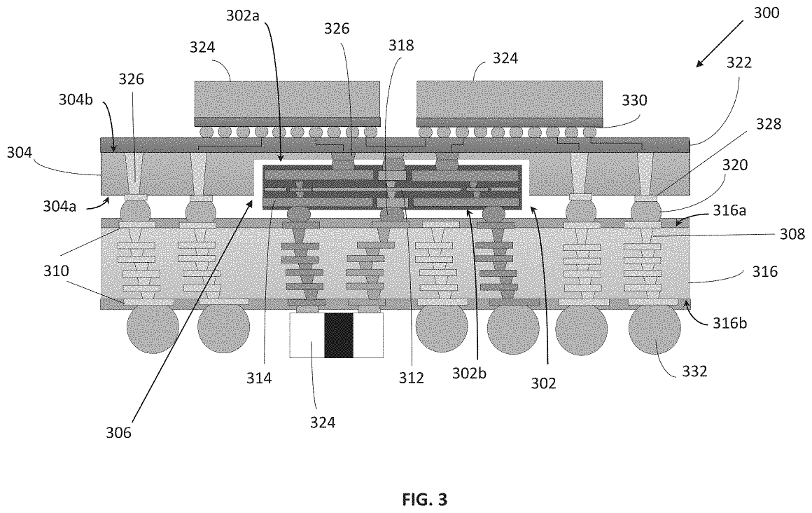

FIG. 3 shows a cross-sectional view of an electronic assembly according to another aspect of the present disclosure for improved device power integrity and miniaturization. The electronic assembly 300 may be similar to the electronic assembly 100 of FIG. 1A and may include additional variations and components as described below.

In various aspects, the electronic assembly 300 may include a first substrate 304. In various aspects, the first substrate 304 may be, e.g., a silicon or a glass interposer substrate. The first substrate 304 may include a first surface 304a, an opposing second surface 304b and a recess opening 306 extending through the first surface 304a. In the aspect shown in FIG. 3, the recess opening may extend from the first surface 304a towards, but not contacting, the second surface 304b.

The first substrate 304 may include a plurality of through silicon vias (TSVs) 326 embedded therein. The first substrate 304 may further include a plurality of first contact pads 328 at the first surface 304a.

In various aspects, the power delivery mold frame 302 may include a first mold surface 302a and an opposing second mold surface 302b, and may be arranged in the recess opening 306. The power delivery mold frame 302 may be coupled to the first substrate 304 through the first mold surface 302a. In one aspect, the power delivery mold frame 302 may include a plurality of first metal planes 312 and a plurality of second metal planes 314. In various aspects, the plurality of second metal planes 314 may be arranged adjacent the plurality of first metal planes 312. The plurality of first metal planes 312 and the plurality of second metal planes 314 may extend between the first and second mold surfaces 302a, 302b to facilitate a reduced AC loop inductance. In an aspect, a plurality of first and second metal planes 312, 314 may extend in parallel to the first and second mold surfaces 302a, 302b.

In various aspects, the power delivery mold frame 302 may include one or more mold layers. For example, the one or more mold layers may be an epoxy polymer resin layer or a silicone layer.

In various aspects, the plurality of first and second metal planes 312, 314 may be spaced apart by the one or more mold layers. In one aspect, the plurality of first metal planes 312 may be associated to a ground reference voltage (Vss). In one aspect, the plurality of second metal planes 314 may be associated to a power supply reference voltage (Vcc). In an aspect, the power delivery mold frame 302 may extend beyond the first surface 304a to utilize an area or stand-off gap between the first substrate 304 and a second substrate 316 for a high-density power delivery network.

In various aspects, the plurality of first metal planes 312 may include a first thickness or volume and the plurality of second metal planes 314 may include a second thickness or volume. Advantageously, the second thickness or volume may be configured to be equal or greater than the first thickness or volume for a reduced DC resistance and an improved current carrying capacity.

In various aspects, the power delivery mold frame 302 may include a thickness ranging from 100 μm to 900 μm. In other aspects, the power delivery mold frame 302 may include a dimension ranging from 2 mm×2 mm to 8 mm×8 mm.

In various aspects, the electronic assembly 300 may include the second substrate 316, such as an organic or a ceramic package substrate. The second substrate 316 may include a subsequent first surface 316a and an opposing subsequent second surface 316b.

The second substrate 316 may have contact pads, electrical interconnects and routings, and other features, which may or may not be shown in any of the present figures and which are conventional features known to a person skilled in the art. In the aspect shown in FIG. 3, the second substrate 316 may be coupled to the power delivery mold frame 302 through a plurality of first solder bumps 318 and to the first substrate 304 through a plurality of second solder bumps 320 at a subsequent first surface 316a. The second substrate 316 may include a plurality of solder balls 332 for coupling to, e.g., a motherboard (not shown).

In the aspect shown in FIG. 3 and as mentioned in an earlier paragraph, the second mold surface 302b may extend beyond the first surface 304a. As such, the plurality of first solder bumps 318 may include a first diameter and the plurality of second solder bumps 320 may include a second diameter greater than the first diameter.

In an aspect, the second substrate 316 may include a plurality of metal traces having a third thickness lesser than the second thickness extending between the subsequent first and second surfaces 316a, 316b for signal transmissions.

In various aspects, the first and/or second substrates 304, 316 may include one or more metal redistribution layers (RDLs) 322. The one or more metal redistribution layers (RDLs) 322 may be arranged on the respective second and/or subsequent second surfaces 304b, 316b.

In various aspects, one or more electronic components 324 may be arranged on the respective second and/or subsequent second surfaces 304b, 316b. In the aspect shown in FIG. 3, one electronic component 324 may be coupled to the power delivery mold frame 302 through a plurality of first contact pads 310 and micro-vias 308 at the subsequent second surface 316b. Two additional electronic components 324 may be coupled to the power delivery mold frame 302 through the one or more RDLs 322 and through silicon vias 326 at the second surface 304b. The one or more electronic components 324 may be coupled to the first and/or second substrates 304, 316 through micro-bumps 330.

In various aspects, the one or more electronic components 324 may include a computing and/or transceiver active device, e.g., a central processing unit (CPU), a graphic processing unit (GPU), a memory device, a neural network accelerator, a field programmable gate array (FPGA), a platform controller hub (PCH) chipset, or an input-output (I/O) tile. In other aspects, the one or more electronic components 324 may include a passive component, e.g., a voltage regulator, an inductor, or a capacitor.

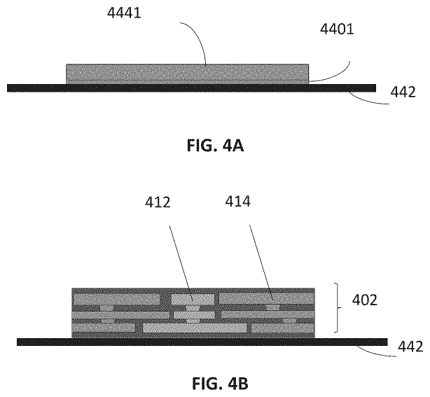

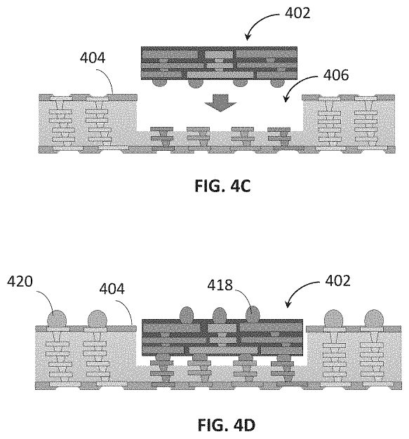

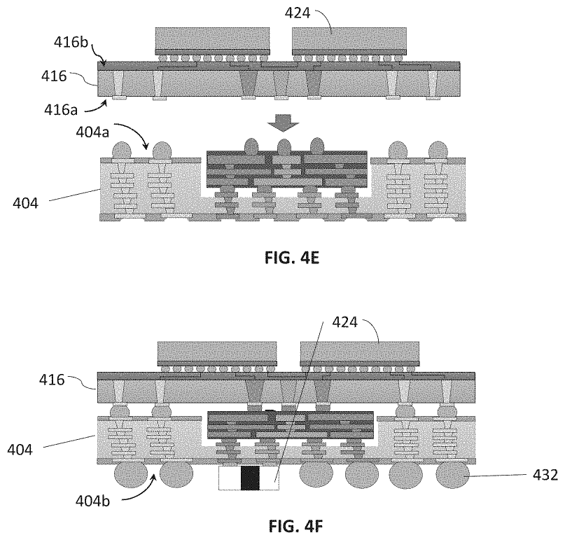

FIGS. 4A through 4F show cross-sectional views directed to an exemplary simplified process flow for forming an electronic assembly according to an aspect that is generally similar to that shown in FIG. 1A of the present disclosure.

FIG. 4A shows formation of a metal plane of a power delivery mold frame. First, a first mold layer 4401 may be formed on a carrier 442. Next, a first metal layer 4441, e.g., copper, may be formed on the first mold layer 4401. Conventional techniques may be employed, such as but not limited to, compression/transfer molding, metal lamination/etching process.

FIG. 4B shows formation of a power delivery network module build-up, i.e., the power delivery mold frame 402. The first metal layer 4441 may be divided into different regions to form a plurality of metal planes, e.g., a plurality of first and second metal planes arranged adjacent to one another. The steps in FIG. 4A may be repeated such that more than one mold layer and more than one metal plane may be formed sequentially. In other words, the plurality of first and second metal planes 412, 414 may be spaced apart by the one or more mold layers. The power delivery mold frame 402 may subsequently be detached from the carrier 442. Conventional techniques may be employed, such as but not limited to, compression/transfer molding, laser/mechanical drilling, metal plating, etching process.

FIG. 4C shows attachment of the power delivery mold frame 402 to a first substrate 404 in a recess opening 406 therein. Conventional techniques may be employed, such as but not limited to, surface mounting/solder reflow process. The first substrate 404 may have contact pads, electrical interconnects and routings, and other features, which may or may not be shown in any of the present figures and which are conventional features known to a person skilled in the art. The power delivery mold frame 402 may include solder bumps for coupling to the first substrate 404.

FIG. 4D shows attachment of first and second solder bumps 418, 420 on the power delivery mold frame 402 and the first substrate 404, respectively. Conventional techniques may be employed, such as but not limited to, solder paste printing and/or solder reflow process.

FIG. 4E shows attachment of a second substrate 416 to the power delivery mold frame 402 and the first substrate 404. The second substrate 416 may include a subsequent first surface 416a and an opposing subsequent second surface 416b. The second substrate 416 may include a plurality of electronic components 424 coupled to the subsequent second surface 416b. The second substrate 416 may include conventional through silicon vias (TSVs) and contact pads. The second substrate 416 may be coupled to the first substrate 404 at a first surface 404a of the first substrate 404. Conventional techniques may be employed, such as but not limited to, solder reflow/thermal compression bonding process.

FIG. 4F shows attachment of solder balls 432 and additional electronic component 424 on a second surface 404b of the first substrate 404 to complete the formation of the electronic assembly of FIG. 1A. Conventional techniques may be employed, such as but not limited to, solder reflow/thermal compression bonding process. Solder balls 432 may be coupled to a motherboard (not shown).

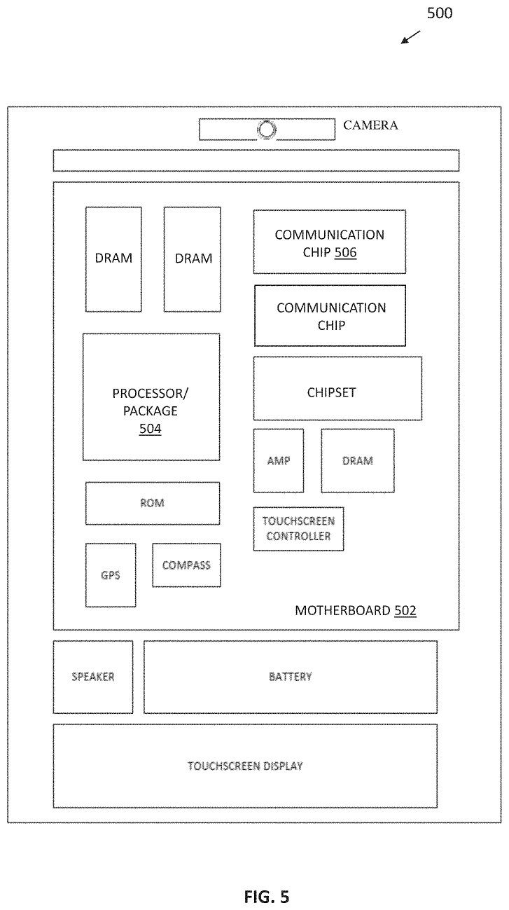

Aspects of the present disclosure may be implemented into a system using any suitable hardware and/or software. FIG. 5 schematically illustrates a computing device 500 that may include an electronic assembly as described herein, in accordance with some aspects. The computing device 500 may house a board such as a motherboard 502. The motherboard 502 may include a number of components, including but not limited to a processor 504 and at least one communication chip 506. The processor 504, which may have the electronic assembly according to the present disclosure, may be physically and electrically coupled to the motherboard 502. In some implementations, the at least one communication chip 506 may also be physically and electrically coupled to the motherboard 502. In further implementations, the communication chip 506 may be part of the processor or package 504.

Depending on its applications, computing device 500 may include other components that may or may not be physically and electrically coupled to the motherboard 502. These other components may include, but are not limited to, volatile memory (e.g. DRAM), non-volatile memory (e.g. ROM), flash memory, a graphics processor, a digital signal processor, a cryptoprocessor, a chipset, an antenna, a display, a touchscreen display, a touchscreen controller, a battery, an audio codec, a video codec, a power amplifier, a global positioning system (GPS) device, a compass, a Geiger counter, an accelerometer, a gyroscope, a speaker, a camera, and a mass storage device (such as hard disk drive, compact disk (CD), digital versatile disk (DVD), and so forth). In another aspect, the processor 504 of the computing device 500 may be packaged in an electronic assembly as described herein, and/or other semiconductor devices may be packaged together in an electronic assembly as described herein.

The communication chip 506 may enable wireless communications for the transfer of data to and from the computing device 500. The term “wireless” and its derivatives may be used to describe circuits, devices, systems, methods, techniques, communications channels, etc. that may communicate data through the use of modulated electromagnetic radiation through a non-solid medium. The term does not imply that the associated devices do not contain any wires, although in some aspects they might not. The communication chip 506 may implement any of a number of wireless standards or protocols, including but not limited to Institute for Electrical and Electronic Engineers (IEEE) standards including Wi-Fi (IEEE 502.11 family), IEEE 502.16 standards (e.g., IEEE 502.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 502.16 compatible BWA networks are generally referred to as WiMAX networks, an acronym that stands for Worldwide Interoperability for Microwave Access, which is a certification mark for products that pass conformity and interoperability tests for the IEEE 502.16 standards.

The communication chip 506 may also operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 506 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 506 may operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. The communication chip 506 may operate in accordance with other wireless protocols in other aspects.

The computing device 500 may include a plurality of communication chips 506. For instance, a first communication chip 506 may be dedicated to shorter range wireless communications such as Wi-Fi and Bluetooth and a second communication chip 506 may be dedicated to longer range wireless communications such as GPS, EDGE, GPRS, CDMA, WiMAX, LTE, Ev-DO, and others.

In various implementations, the computing device 500 may be a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder. In an aspect, the computing device 500 may be a mobile computing device. In further implementations, the computing device 500 may be any other electronic device that processes data.

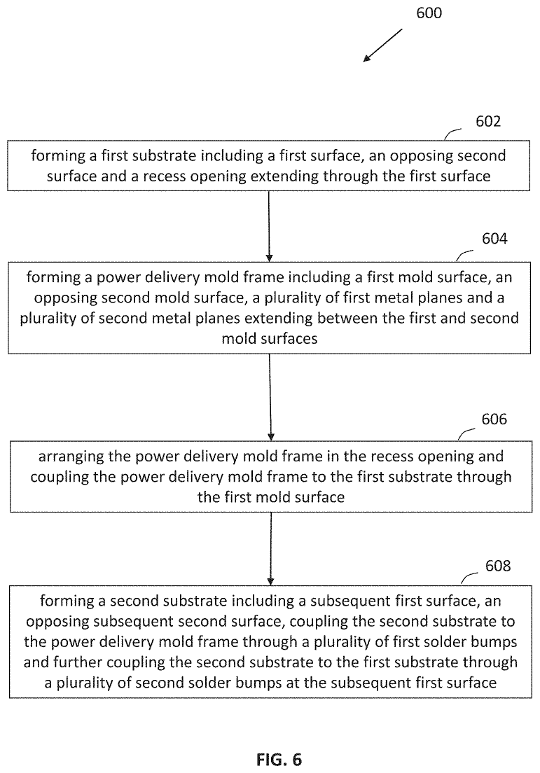

FIG. 6 shows a flow chart illustrating a method 600 of forming an electronic assembly according to an aspect of the present disclosure.

At operation 602, the method 600 may include forming a first substrate including a first surface, an opposing second surface and a recess opening extending through the first surface.

At operation 604, the method 600 may also include forming a power delivery mold frame including a first mold surface, an opposing second mold surface, a plurality of first metal planes and a plurality of second metal planes extending between the first and second mold surfaces.

At operation 606, the method 600 may include arranging the power delivery mold frame in the recess opening and coupling the power delivery mold frame to the first substrate through the first mold surface.

At operation 608, the method 600 may further include forming a second substrate including a subsequent first surface, an opposing subsequent second surface, coupling the second substrate to the power delivery mold frame through a plurality of first solder bumps and further coupling the second substrate to the first substrate through a plurality of second solder bumps at the subsequent first surface.

It will be understood that the above operations described above relating to FIG. 6 are not limited to this particular order. Any suitable, modified order of operations may be used.

### EXAMPLES

Example 1 may include an electronic assembly. The electronic assembly may include a first substrate including a first surface, an opposing second surface and a recess opening extending through the first surface. The electronic assembly may also include a power delivery mold frame including a first mold surface, an opposing second mold surface, a plurality of first metal planes and a plurality of second metal planes extending between the first and second mold surfaces, the power delivery mold frame arranged in the recess opening and coupled to the first substrate through the first mold surface. The electronic assembly may further include a second substrate including a subsequent first surface, an opposing subsequent second surface, the second substrate coupled to the power delivery mold frame through a plurality of first solder bumps and further coupled to the first substrate through a plurality of second solder bumps at the subsequent first surface.

Example 2 may include the electronic assembly of example 1 and/or any other example disclosed herein, the respective first substrate and the second substrate may include a silicon substrate, a glass substrate, an organic substrate, or a ceramic substrate.

Example 3 may include the electronic assembly of example 1 and/or any other example disclosed herein, the power delivery mold frame may further include one or more mold layers, wherein the plurality of first and second metal planes may be spaced apart by the one or more mold layers.

Example 4 may include the electronic assembly of example 1 and/or any other example disclosed herein, the plurality of first metal planes may be arranged adjacent the plurality of second metal planes.

Example 5 may include the electronic assembly of example 1 and/or any other example disclosed herein, the plurality of first metal planes may include a first thickness or volume, the plurality of second metal planes may include a second thickness or volume equal or greater than the first thickness or volume.

Example 6 may include the electronic assembly of example 1 and/or any other example disclosed herein, the plurality of first metal planes may be associated to a ground reference voltage (Vss), and the plurality of second metal planes may be associated to a power supply reference voltage (Vcc).

Example 7 may include the electronic assembly of example 1 and/or any other example disclosed herein, the second mold surface may extend beyond the first surface.

Example 8 may include the electronic assembly of example 1 and/or any other example disclosed herein, the plurality of first solder bumps may include a first diameter and the plurality of second solder bumps may include a second diameter greater than the first diameter.

Example 9 may include the electronic assembly of example 1 and/or any other example disclosed herein, the electronic assembly may further include one or more metal redistribution layers (RDLs) arranged on the respective second and/or subsequent second surfaces.

Example 10 may include the electronic assembly of example 1 and/or any other example disclosed herein, the electronic assembly may further include one or more electronic components arranged on the respective second and/or subsequent second surfaces and coupled to the power delivery mold frame through a plurality of substrate contact pads and vias.

Example 11 may include the electronic assembly of example 10 and/or any other example disclosed herein, the one or more electronic components may include a central processing unit (CPU), a graphic processing unit (GPU), a memory device, a neural network processor, an input-output (I/O) tile, a voltage regulator, an inductor, or a capacitor.

Example 12 may include a computing device. The computing device may include a circuit board and an electronic assembly coupled to the circuit board. The electronic assembly may include a first substrate including a first surface, an opposing second surface and a recess opening extending through the first surface. The electronic assembly may also include a power delivery mold frame including a first mold surface, an opposing second mold surface, a plurality of first metal planes and a plurality of second metal planes extending between the first and second mold surfaces, the power delivery mold frame arranged in the recess opening and coupled to the first substrate through the first mold surface. The electronic assembly may further include a second substrate including a subsequent first surface, an opposing subsequent second surface, the second substrate coupled to the power delivery mold frame through a plurality of first solder bumps and further coupled to the first substrate through a plurality of second solder bumps at the subsequent first surface.

Example 13 may include the computing device of any one of examples 1 to 12 disclosed herein, wherein the power delivery mold frame may further include one or more mold layers, wherein the plurality of first and second metal planes may be spaced apart by the one or more mold layers.

Example 14 may include the computing device of any one of examples 1 to 13 disclosed herein, wherein the plurality of first metal planes may be arranged adjacent the plurality of second metal planes.

Example 15 may include the computing device of any one of examples 1 to 14 disclosed herein, wherein the plurality of first metal planes may include a first thickness or volume, the plurality of second metal planes may include a second thickness or volume equal or greater than the first thickness or volume.

Example 16 may include the computing device of any one of examples 1 to 15 disclosed herein, wherein the plurality of first metal planes may be associated to a ground reference voltage (Vss), and the plurality of second metal planes may be associated to a power supply reference voltage (Vcc).

Example 17 may include a method. The method may include forming a first substrate including a first surface, an opposing second surface and a recess opening extending through the first surface. The method may also include forming a power delivery mold frame including a first mold surface, an opposing second mold surface, a plurality of first metal planes and a plurality of second metal planes extending between the first and second mold surfaces. The method may include arranging the power delivery mold frame in the recess opening and coupling the power delivery mold frame to the first substrate through the first mold surface. The method may further include forming a second substrate including a subsequent first surface, an opposing subsequent second surface, coupling the second substrate to the power delivery mold frame through a plurality of first solder bumps and further coupling the second substrate to the first substrate through a plurality of second solder bumps at the subsequent first surface.

Example 18 may include the method of example 17 and/or any other example disclosed herein, wherein the power delivery mold frame may further include one or more mold layers, and spacing the plurality of first and second metal planes apart by the one or more mold layers.

Example 19 may include the method of example 17 and/or any other example disclosed herein, further including arranging the plurality of first metal planes adjacent the plurality of second metal planes.

Example 20 may include the method of example 17 and/or any other example disclosed herein, wherein the plurality of first metal planes may include a first thickness or volume, the plurality of second metal planes may include a second thickness or volume equal or greater than the first thickness or volume.

The term “comprising” shall be understood to have a broad meaning similar to the term “including” and will be understood to imply the inclusion of a stated integer or operation or group of integers or operations but not the exclusion of any other integer or operation or group of integers or operations. This definition also applies to variations on the term “comprising” such as “comprise” and “comprises”.

The term “coupled” (or “connected”) used herein may be understood as electrically coupled or as mechanically coupled, e.g., attached or fixed or mounted, or just in contact without any fixation, and it will be understood that both direct coupling and indirect coupling (in other words, coupling without direct contact) may be provided.

While the present disclosure has been particularly shown and described with reference to specific aspects, it should be understood by persons skilled in the art that various changes in form and detail may be made therein without departing from the scope of the present disclosure as defined by the appended claims. The scope of the present disclosure is thus indicated by the appended claims and all changes which come within the meaning and range of equivalency of the claims are therefore intended to be embraced.

What is claimed is:

1. An electronic assembly comprising:
a first substrate comprising a first surface, an opposing second surface and a recess opening extending through the first surface;
a power delivery mold frame comprising a first mold surface, an opposing second mold surface, a plurality of first metal planes and a plurality of second metal planes extending between the first and second mold surfaces, the power delivery mold frame arranged in the recess opening and coupled to the first substrate through the first mold surface; and
a second substrate comprising a subsequent first surface, an opposing subsequent second surface, the second substrate coupled to the power delivery mold frame through a plurality of first solder bumps and further coupled to the first substrate through a plurality of second solder bumps at the subsequent first surface.

2. The electronic assembly of claim 1, wherein the respective first substrate and the second substrate comprise a silicon substrate, a glass substrate, an organic substrate, or a ceramic substrate.

3. The electronic assembly of claim 1, wherein the power delivery mold frame further comprises one or more mold layers, wherein the plurality of first and second metal planes are spaced apart by the one or more mold layers.

4. The electronic assembly of claim 1, wherein the plurality of first metal planes is arranged adjacent the plurality of second metal planes.

5. The electronic assembly of claim 1, wherein the plurality of first metal planes comprises a first thickness or volume, the plurality of second metal planes comprises a second thickness or volume equal or greater than the first thickness or volume.

6. The electronic assembly of claim 1, wherein the plurality of first metal planes is associated to a ground reference voltage (Vss), and the plurality of second metal planes is associated to a power supply reference voltage (Vcc).

7. The electronic assembly of claim 1, wherein the second mold surface extends beyond the first surface.

8. The electronic assembly of claim 1, wherein the plurality of first solder bumps comprises a first diameter and the plurality of second solder bumps comprises a second diameter greater than the first diameter.

9. The electronic assembly of claim 1, further comprising one or more metal redistribution layers (RDLs) arranged on the respective second and/or subsequent second surfaces.

10. The electronic assembly of claim 1, further comprising one or more electronic components arranged on the respective second and/or subsequent second surfaces and coupled to the power delivery mold frame through a plurality of substrate contact pads and vias.

11. The electronic assembly of claim 10, wherein the one or more electronic components comprise a central processing unit (CPU), a graphic processing unit (GPU), a memory device, a neural network processor, an input-output (I/O) tile, a voltage regulator, an inductor, or a capacitor.

12. A computing device comprising:
a circuit board; and
an electronic assembly coupled to the circuit board, the electronic assembly comprising:
a first substrate comprising a first surface, an opposing second surface and a recess opening extending through the first surface;
a power delivery mold frame comprising a first mold surface, an opposing second mold surface, a plurality of first metal planes and a plurality of second metal planes extending between the first and second mold surfaces, the power delivery mold frame arranged in the recess opening and coupled to the first substrate through the first mold surface; and
a second substrate comprising a subsequent first surface, an opposing subsequent second surface, the second substrate coupled to the power delivery mold frame through a plurality of first solder bumps and further coupled to the first substrate through a plurality of second solder bumps at the subsequent first surface.

13. The computing device of claim 12, wherein the power delivery mold frame further comprises one or more mold layers, wherein the plurality of first and second metal planes are spaced apart by the one or more mold layers.

14. The computing device of claim 12, wherein the plurality of first metal planes is arranged adjacent the plurality of second metal planes.

15. The computing device of claim 12, wherein the plurality of first metal planes comprises a first thickness or volume, the plurality of second metal planes comprises a second thickness or volume equal or greater than the first thickness or volume.

16. The computing device of claim 12, wherein the plurality of first metal planes is associated to a ground reference voltage (Vss), and the plurality of second metal planes is associated to a power supply reference voltage (Vcc).

17. A method comprising:
forming a first substrate comprising a first surface, an opposing second surface and a recess opening extending through the first surface;
forming a power delivery mold frame comprising a first mold surface, an opposing second mold surface, a plurality of first metal planes and a plurality of second metal planes extending between the first and second mold surfaces;
arranging the power delivery mold frame in the recess opening and coupling the power delivery mold frame to the first substrate through the first mold surface; and
forming a second substrate comprising a subsequent first surface, an opposing subsequent second surface, coupling the second substrate to the power delivery mold frame through a plurality of first solder bumps and further coupling the second substrate to the first substrate through a plurality of second solder bumps at the subsequent first surface.

18. The method of claim 17, wherein the power delivery mold frame further comprises one or more mold layers, and spacing the plurality of first and second metal planes apart by the one or more mold layers.

19. The method of claim 17, further comprising arranging the plurality of first metal planes adjacent the plurality of second metal planes.

20. The method of claim 17, wherein the plurality of first metal planes comprises a first thickness or volume, the plurality of second metal planes comprises a second thickness or volume equal or greater than the first thickness or volume.
